(19) United States
(12) Patent Application Publication
(10) Pub. No.: US 2026/0215303 A1
(43) Pub. Date: Jul. 23, 2026

(54) SEMICONDUCTOR DEVICE

(71) Applicants: Global Unichip Corporation, Hsinchu (TW); Taiwan Semiconductor Manufacturing Company, Ltd., Hsinchu (TW)

(72) Inventors: Liang-Kai Chen, Hsinchu (TW); Sheng-Fan Yang, Hsinchu (TW); Chih-Chiang Hung, Hsinchu (TW); Wen-Yi Jian, Hsinchu (TW); Igor Elkanovich, Hsinchu (TW)

(73) Assignees: Global Unichip Corporation, Hsinchu (TW); Taiwan Semiconductor Manufacturing Company, Ltd., Hsinchu (TW)

(21) Appl. No.: 19/035,743

(22) Filed: Jan. 23, 2025

(51) Int. Cl. H01L 23/538; H01L 23/00; H01L 25/18

(52) U.S. Cl. CPC H10W 70/65; H10W 70/611; H10W 90/00; H10W 90/401; H10W 90/724

(57) ABSTRACT

An electronic device includes semiconductor dies, an interposer, and a passive component. The semiconductor dies are laterally spaced from each other by a die gap region. The semiconductor dies are bonded onto a first surface of the interposer, wherein the interposer provides a gap electric transmission pathway in the die gap region, the gap electric transmission pathway extends from the first surface of the interposer to a second surface of the interposer, and the second surface is opposite to the first surface. The passive component is bonded onto the second surface of the interposer, and located in the die gap region, wherein the passive component is electrically connected to the semiconductor dies through the gap electric transmission pathway.

### BACKGROUND

### Technical Field

The disclosure is related to a semiconductor device.

### Description of Related Art

The packages of integrated circuits are becoming increasing complex, with more device dies packaged in the same package to form a system having more functions. Integrated Passive Devices (IPDs), which are discrete devices, are often used in the packages. The IPDs are electrically connected to the semiconductor dies in the packages and help to reduce the transmission loss and the power consumption in the packages.

### SUMMARY

The disclosure is directed to an electronic device providing a short transmission path between the semiconductor dies and the passive component bonded to opposite sides of the interposer.

According to embodiments of the disclosure, an electronic device includes semiconductor dies, an interposer, and a passive component. The semiconductor dies are laterally spaced from each other by a die gap region. The semiconductor dies are bonded onto a first surface of the interposer, wherein the interposer provides a gap electric transmission pathway in the die gap region, the gap electric transmission pathway extends from the first surface of the interposer to a second surface of the interposer, and the second surface is opposite to the first surface. The passive component is bonded onto the second surface of the interposer, and located in the die gap region, wherein the passive component is electrically connected to the semiconductor dies through the gap electric transmission pathway.

According to embodiments of the disclosure, an electronic device includes semiconductor dies and an interposer. The semiconductor dies are laterally spaced from each other by a die gap region. The semiconductor dies are bonded onto the interposer, wherein the interposer includes a substrate, a redistribution circuitry structure and a plurality of embedded passive components. The redistribution circuitry structure is disposed on the substrate and includes a dielectric structure and metal layers embedded in the dielectric structure to provide a gap electric transmission pathway in the die gap region. The embedded passive components are disposed between the substrate and the redistribution circuitry structure. At least one of the embedded passive components is electrically connected to the semiconductor dies through the gap electric transmission pathway.

In light of the above, the electronic device having semiconductor dies laterally spaced from each other provides an interposer having the gap electric transmission pathway in the die gap region between semiconductor dies for electrically connecting between the semiconductor dies and the passive component bonded on different surfaces of the interposer. The gap electric transmission pathway and the passive component are located in the die gap region to for reducing electric transmission path between the passive component and the semiconductor dies, which ensures the effect of the passive component to achieve better device performance.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 schematically illustrates an electronic device from a side view in accordance with some embodiments of the disclosure.

FIG. 2 schematically illustrates a sectional view of an electronic device in accordance with some embodiments of the disclosure.

FIG. 3 schematically illustrates a top view of a portion of the metal layer Mx in the redistribution circuitry structure of FIG. 2 in accordance with some embodiments of the disclosure.

FIG. 4 schematically illustrates a top view of a portion of the metal layer M1 in the redistribution circuitry structure of FIG. 2 in accordance with some embodiments of the disclosure.

FIG. 5 schematically illustrates a top view of a portion of the metal layer M1 in the redistribution circuitry structure of FIG. 2 in accordance with some embodiments of the disclosure.

FIG. 6 schematically illustrates a top view of a portion of the metal layer M1 in the redistribution circuitry structure of FIG. 2 in accordance with some embodiments of the disclosure.

FIG. 7 schematically illustrates a sectional view of an electronic device in accordance with some embodiments of the disclosure.

FIG. 8 schematically illustrates a sectional view of an electronic device in accordance with some embodiments of the disclosure.

### DESCRIPTION OF THE EMBODIMENTS

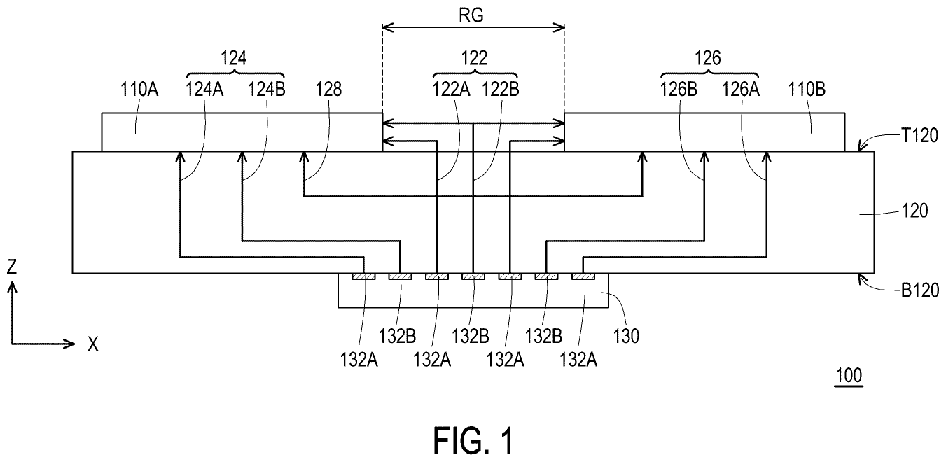

FIG. 1 schematically illustrates an electronic device from a side view in accordance with some embodiments of the disclosure. In FIG. 1, an electronic device 100 includes semiconductor dies 110A and 110B, an interposer 120 and a passive component 130. For descriptive purpose, FIG. 1 shows the components using simple patterns which does not intend to limit the real structure of these components. The semiconductor dies 110A and 110B are bonded onto a first surface T120 of the interposer 120 and are located laterally spaced from each other in X direction by a die gap region RG. The passive component 130 is bonded onto a second surface B120 of the interposer 120 which is opposite to the first surface T120. In some embodiments, the passive component 130 is located in the die gap region RG. The interposer 120 may provide gap electric transmission pathways 122 in the die gap region RG, and the passive component 130 is electrically connected to the semiconductor dies 110A and 110B through the gap electric transmission pathways 122. In some embodiments, the gap electric transmission pathways 122 may include a first gap electric transmission pathway 122A and a second gap electric transmission pathway 122B delivering a different supply voltage from the first gap electric transmission pathway 122A.

The semiconductor dies 110A and 110B may include transistors therein to enable the required circuitry function. Each of the semiconductor dies 110A and 110B may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof. In some embodiments, the semiconductor dies 110A and 110B are signally communicated to each other.

The interposer 120 is a component at least including a redistribution circuitry structure that establishes electric transmission pathways enabling the required electric connections for the semiconductor dies 110A and 110B. In some embodiments, the first gap electric transmission pathway 122A and the second gap electric transmission pathway 122B provided by the interposer 120 extend through the interposer 120 in the thickness direction (Z direction) and laterally extend from the die gap region RG toward the semiconductor dies 110A and 110B in the X direction. For example, each of the first gap electric transmission pathway 122A and the second gap electric transmission pathway 122B may extend from the first surface T120 to the second surface B120. The first gap electric transmission pathway 122A and the second gap electric transmission pathway 122B are routed between the semiconductor dies 110A and 110B bonded onto the first surface T120 and the passive component 130 bonded onto the second surface B120.

The passive component 130 may be a decoupling capacitor integrated in the electronic device 100, such as Silicon Capacitor (Si-Cap). The passive component 130 may be fabricated in advance as a package and is bonded onto the second surface B120 of the interposer 120 as shown in FIG. 1. The passive component 130 may be called as an integrated passive device (IPD) in some applications. The passive component 130 may include first bonding pads 132A and second bonding pads 132B that are bonded to the interposer 120. In some embodiments, the first bonding pads 132A are power pads for transmitting the electric power, such as VDD, and the second bonding pads 132B are ground pads that are electrically ground. A least one of the first bonding pads 132A is electrically connected to the semiconductor dies 110A and 110B through the first gap electric transmission pathway 122A and at least one of the second bonding pads 132B is electrically connected to the semiconductor dies 110A and 110B through the second gap electric transmission pathway 122B. In some embodiments, the first bonding pads 132A are configure to deliver the electric power and the second bonding pads 132B are electrically connected to the ground. Accordingly, the first gap electric transmission pathway 122A transmits the electric power and the second gap electric transmission pathway 122B is electrically grounded.

In some embodiments, the interposer 120 include other electric transmission pathways such as underneath electric transmission pathways 124 disposed underneath the semiconductor dies 110A and underneath electric transmission pathways 126 disposed underneath the semiconductor dies 110B. The underneath electric transmission pathways 124 include a first underneath electric transmission pathway 124A and a second underneath electric transmission pathway 124B transmitting a different supply voltage from the first underneath electric transmission pathway 124A. The first underneath electric transmission pathway 124A and the second underneath electric transmission pathway 124B are located underneath the semiconductor die 110A and electrically connected between the semiconductor die 110A and the passive component 130. For example, the first underneath electric transmission pathway 124A is connected to one of the first bonding pads 132A of the passive component 130 to deliver the electric power, and the second underneath electric transmission pathway 124B is connected to one of the second bonding pad 132B to be electrically grounded.

The underneath electric transmission pathways 126 include a first underneath electric transmission pathway 126A and a second underneath electric transmission pathway 126B transmitting a different supply voltage from the first underneath electric transmission pathway 126A. The first underneath electric transmission pathway 126A and the second underneath electric transmission pathway 126B are located underneath the semiconductor die 110B and electrically connected between the semiconductor die 110B and the passive component 130. For example, the first underneath electric transmission pathway 126A is connected to one of the first bonding pads 132A of the passive component 130 to deliver the electric power, and the second underneath electric transmission pathway 126B is connected to one of the second bonding pad 132B to be electrically grounded.

Accordingly, the passive component 130 may be electrically connected to the semiconductor dies 110A and 110B through the gap electric transmission pathways 122 in the die gap region RD as well as the underneath electric transmission pathways 124 underneath the semiconductor die 110A and the second underneath electric transmission pathways 126 underneath the semiconductor die 110B. In some embodiments, the interposer 120 may further provide a lateral signal transmission pathway 128 that achieves the signal transmission between the semiconductor dies 110A and 110B in a lateral direction such as the X direction.

In the embodiment, the first gap electric transmission pathway 122A, the second gap electric transmission pathway 122B and the passive component 130 are located in the die gap region RD between the semiconductor die 110A and the semiconductor die 110B, such that the first gap electric transmission pathway 122A and the second gap electric transmission pathway 122B provide shorter transmission paths between the semiconductor dies 110A and 110B and the passive component 130 than the underneath electric transmission pathways 124 and the underneath electric transmission pathways 126, which helps to reduce the transmission resistance and the inductance. The gap electric transmission pathways 122 provide optimized electric transmission effects that may reduce the transmission loss caused by inductor DC resistance (DCR) and reactance.

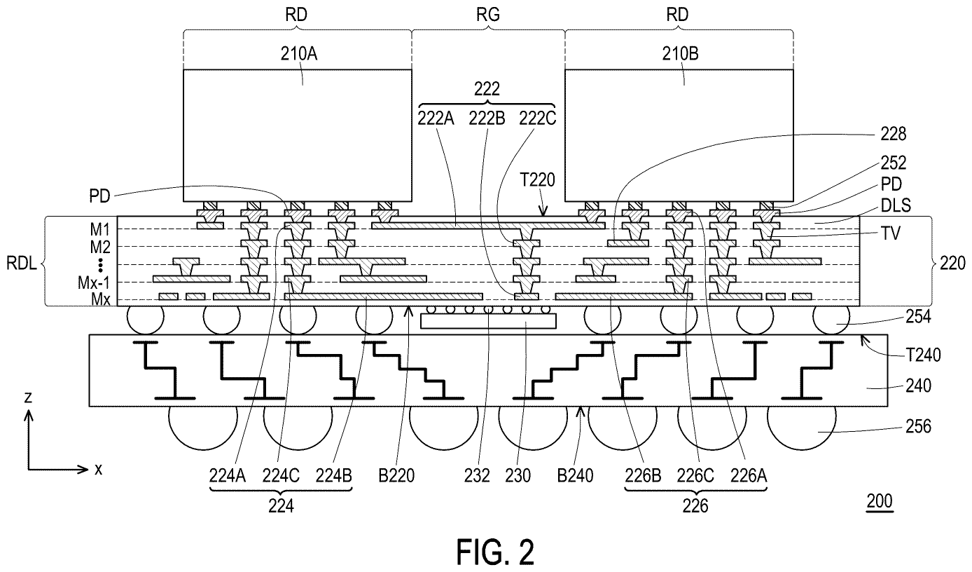

FIG. 2 schematically illustrates a sectional view of an electronic device in accordance with some embodiments of the disclosure. An electronic device 200 shown in FIG. 2 includes semiconductor dies 210A and 210B, an interposer 220, a passive component 230 and a package substrate 240. In the embodiment, the electronic device 200 may be considered as an implemented example of the electronic device 100, where the semiconductor dies 210A and 210B are comparable to the semiconductor dies 110A and 110B, the interposer 220 is comparable to the interposer 120 and the passive component 230 is comparable to the passive component 130. The semiconductor dies 110A and 110B are bonded onto the first surface T220 of the interposer 220, for example, through bonding structures 252. The interposer 220 is bonded onto the first surface T240 of the package substrate 240 through bonding structures 254. In addition, conductive connectors 256 are disposed on the second surface B240 of the package substrate 240 and configured for connecting the electronic device 200 to an external device. In some embodiments, the bonding structures 252 may be micro-bumps, the bonding structures 254 may be C4 bumps, and the conductive connectors 256 may be BGA balls, but the disclosure is not limited thereto.

The semiconductor dies 210A and 210B may be considered as implemented examples of the semiconductor dies 110A and 110B depicted in FIG. 1. In some embodiments, each of the semiconductor dies 210A and 210B includes electronic components and interconnected structures fabricated in/on a semiconductor substrate to enable certain circuitry function. The electronic components formed in the semiconductor dies 210A and 210B may include active components such as transistors, passive components such as capacitors, and/or a combination thereof. Referring to the description of FIG. 1, each of the semiconductor dies 210A and 210B may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

The interposer 220 may include a redistribution circuitry structure RDL which includes a dielectric structure DLS and metal layers M1, M2 . . . Mx−1, Mx embedded in the dielectric structure DLS, where x is 5 as an example in the embodiment, but the disclosure is not limited thereto. The dielectric structure DLS is formed by multiple dielectric layers separating each of the metal layers M1 . . . Mx from next one. The dielectric structure DLS may be made of dielectric material such as polyimide and the metal layers may be made of conductive metal material such as copper, but the disclosure is not limited thereto. The metal layers M1 . . . Mx are sequentially arranged from the first surface T220 of the interposer 220 to the second surface B220 of the interposer 220 at different levels. The metal layers M1 . . . Mx are patterned to form discrete conductive features for establishing required electric transmission routing. For connecting different conductive features in different metal layers M1 . . . Mx, the redistribution circuitry structure RDL further includes through vias TV and each of the trough vias connects the gap conductive features in adjacent two of the metal layers M1 . . . Mx.

In the embodiment, the interposer 220 may further include bonding pads PD disposed on the first surface T220 thereof. The bonding pads PD are connected to the metal layer M1 most adjacent to the first surface T220 and the semiconductor dies 210A and 210B are bonded to the bonding pads PD through the bonding structures 252. In some embodiments, the bonding pads PD may be made of a conductive metal material different from the metal layers M1 . . . Mx. For example, the bonding pads PD may be made of aluminum, but the disclosure is not limited thereto. Further bonding pads (not shown) may be disposed on the second surface B220 of the interposer 220 to serve as bottom bonding pads and the bonding structures 254 are disposed on the bottom bonding pads, but the disclosure is not limited thereto. In some embodiments, the dielectric structure DLS may exposed a portion of the metal layer Mx most adjacent to the second surface B220 of the interposer 220 and the bonding structures 254 are disposed on the exposed portion of the metal layer Mx to form the required electric connection.

The passive component 230 is bonded to the second surface B220 of the interposer 220 through the bonding structures 232 and electrically connected to the semiconductor dies 210A and 210B through corresponding metal features formed by the metal layers M1 . . . Mx of the redistribution circuitry structure RDL. In some embodiments, the bonding structures 232 may be conductive bumps connecting to the bonding pads (not shown) of the passive component 230. For example, a portion of the bonding structures 232 may deliver electric power and be connected to the first bonding pads 132A depicted in FIG. 1 and another portion of the bonding structures 232 may connect to ground and be connected to the second bonding pads 132B depicted in FIG. 1.

In the embodiment, the semiconductor die 210A is laterally spaced from the semiconductor die 210B in X direction by a die gap region RG while the regions where the semiconductor dies 210A and 210B are considered as die regions RD. The passive component 230 is located in the die gap region RG. The metal layers M1 . . . Mx of the redistribution circuitry structure RDL construct gap conductive features 222 located in the die gap region RG, underneath conductive features 224 underneath the semiconductor die 210A and underneath conductive features 226 underneath the semiconductor die 210B. For descriptive purpose, FIG. 2 only shows one of the gap conductive features 222, one of the underneath conductive features 224 and one of the underneath conductive features 226. The gap conductive feature 222 is located in the die gap region RG and right above the passive component 230, and the underneath conductive feature 224 and the underneath conductive feature 226 are located in the die regions RD and underneath the semiconductor dies 210A and 210B. In some embodiments, the gap conductive feature 222 may be considered as an example for implementing each of the first gap electric transmission pathway 122A and the second gap electric transmission pathway 122B, the underneath conductive feature 224 may be considered as an example for implementing each of the first underneath electric transmission pathway 124A and the second underneath electric transmission pathway 124B, and the underneath conductive feature 226 may be considered as an example for implementing each of the first underneath electric transmission pathway 126A and the second underneath electric transmission pathway 126B.

The gap conductive feature 222 includes a top pattern 222A in the metal layer M1 (the top metal layer of the metal layers M1 . . . Mx), a bottom pattern 222B in the metal layer Mx (the bottom metal layer of the metal layers M1 . . . Mx) and intermediate patterns 222C in the intermediate metal layers M2 . . . Mx−1 between the metal layer M1 and the metal layer Mx. The intermediate patterns 222C establish a continuous electric transmission path between the top pattern 222A and the bottom pattern 222B in the Z direction. In some embodiments, the top pattern 222A, the bottom pattern 222B and the intermediate patterns 222C are mainly located in the die gap region RG. The bottom pattern 222B may be located corresponding and electrically connected to one of the bonding structures 232. The top pattern 222A laterally extends from the die gap region RG toward the semiconductor dies 210A and 210B and partially overlaps the semiconductor dies 210A and 210B. Specifically, corresponding ones of the bonding pads PD for bonding the semiconductor dies 210A and 210B are disposed on and connected to the top pattern 222A. Accordingly, the top pattern 222A is electrically connected with the semiconductor dies 210A and 210B through the corresponding ones of the bonding pads PD. In some embodiments, the intermediate patterns 222C may be stacked along the thickness direction (Z direction) between the top pattern 222A and the bottom pattern 222B so that the gap conductive feature 222 provides a substantial vertical electric transmission pathway between the semiconductor dies 210A and 210B and the passive component 230.

The underneath conductive feature 224 in the die region RD may be electrically connected between the passive component 230 and one of the semiconductor dies, i.e. the semiconductor die 210A. The underneath conductive feature 224 include a top pattern 224A in the metal layer M1, a bottom pattern 224B in the metal layer Mx and intermediate patterns 224C in the intermediate metal layers M2 . . . Mx−1 between the metal layer M1 and the metal layer Mx. The intermediate patterns 224C are arranged along the thickness direction (Z direction) and underneath the semiconductor die 210A to connect between the top pattern 224A and the bottom pattern 224B. One corresponding bonding pad PD is disposed on the top pattern 224A and electrically connected to the semiconductor die 210A through the bonding structure 252. The bottom pattern 224B laterally extends from the die region RD toward the die gap region RG and partially overlaps the passive component 230. In some embodiments, the extending length of the bottom pattern 224B of the underneath conductive feature 224 is greater than the extending length of the top pattern 222A of the gap conductive feature 222 so that the gap conductive feature 222 provides a relative shorter electric transmission path between the semiconductor die 210A and the passive component 230 than the underneath conductive feature 224.

The underneath conductive feature 226 has a structure similar to the underneath conductive feature 224 and is located underneath the semiconductor die 210B to provide an electric transmission between the semiconductor die 210B and the passive component 230. Specifically, the underneath conductive feature 226 includes a top pattern 226A in the metal layer M1, a bottom pattern 226B in the metal layer Mx and intermediate patterns 226C arranged between the top pattern 226A and the bottom pattern 226B in the intermediate metal layers M2 . . . Mx−1 between the metal layer M1 and the metal layer Mx. The redistribution circuitry structure RDL may further includes other conductive features such as a lateral conductive feature 228 in the metal layers M2 . . . Mx−1 between the metal layer M1 and the metal layer Mx and a portion of the lateral conductive feature 228 may be partially extend through the die gap region RG to provide a lateral electric transmission path between the semiconductor die 210A and the semiconductor die 210B, which serves as an example of implementing the lateral signal transmission pathway 128 depicted in FIG. 1.

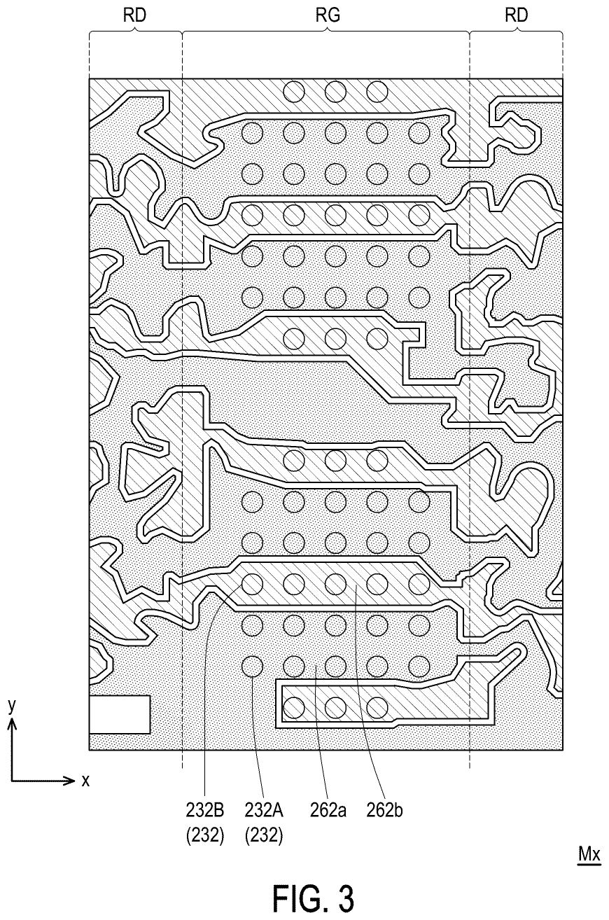

FIG. 3 schematically illustrates a top view of a portion of the metal layer Mx in the redistribution circuitry structure of FIG. 2 in accordance with some embodiments of the disclosure. In some embodiments, the metal layer Mx is configured to form a power delivery network (PDN) for delivering the electric power for the electronic device. For descriptive purpose, FIG. 3 shows the die gap region RG and portions of the die regions RD where the semiconductor dies 210A and 210B depicted in FIG. 2 are located. FIG. 3 shows the metal layer Mx in the die gap region RG and also shows the arrangement of the bonding structures 232 of the passive component 230 depicted in FIG. 2. The bonding structures 232 includes first bonding structures 232A for delivering the electric power and second bonding structures 232B electrically connected to the ground. The first bonding structures 232A are divided into groups arranged along the Y direction. The second bonding structures 232B are interposed between different groups of the first bonding structures 232A, but the disclosure is not limited thereto. As shown in FIG. 3, each group of the first bonding structures 232A includes ten first bonding structures 232A arranged in a 5×2 array as an example, but the disclosure is not limited thereto. The metal layer Mx includes first bottom patterns 262a connected to the first bonding structures 232A and second bottom patterns 262b connected to the second bonding structures 232B. The first bottom patterns 262a and the second bottom patterns 262b are arranged alternately along the Y direction. Each of the first bottom patterns 262a and the second bottom patterns 262b is an elongated pattern extending across the die gap region RG along the X direction to partially overlap the die regions RD at opposite sides of the die gap region RG.

Each of the first bottom patterns 262a and the second bottom patterns 262b may be served as an example for implementing the bottom pattern 222B of the gap conductive feature 222. In the case that the gap conductive feature 222 of FIG. 2 is configured for delivering the electric power to form the first gap electric transmission pathway 122A in FIG. 1, the bottom pattern 222B of the gap conductive feature 222 may be implemented by the first bottom patterns 262a. In the case that the gap conductive feature 222 of FIG. 2 is configured for connecting to the ground to form the second gap electric transmission pathway 122B in FIG. 1, the bottom pattern 222B of the gap conductive feature 222 may be implemented by the second bottom patterns 262b. In some embodiments, each of the first bottom patterns 262a and the second bottom patterns 262b may extend to the die region RD and serve as example for implementing the bottom pattern 224B of the underneath conductive feature 224 or the bottom pattern 226B of the underneath conductive feature 226 depicted in FIG. 2. For example, the bottom pattern 222B of the gap conductive feature 222, the bottom pattern 224B of the underneath conductive feature 224 and the bottom pattern 226B of the underneath conductive feature 226 may be implemented by a common pattern in the die gap region RG, e.g. the first bottom patterns 262a and the second bottom patterns 262b.

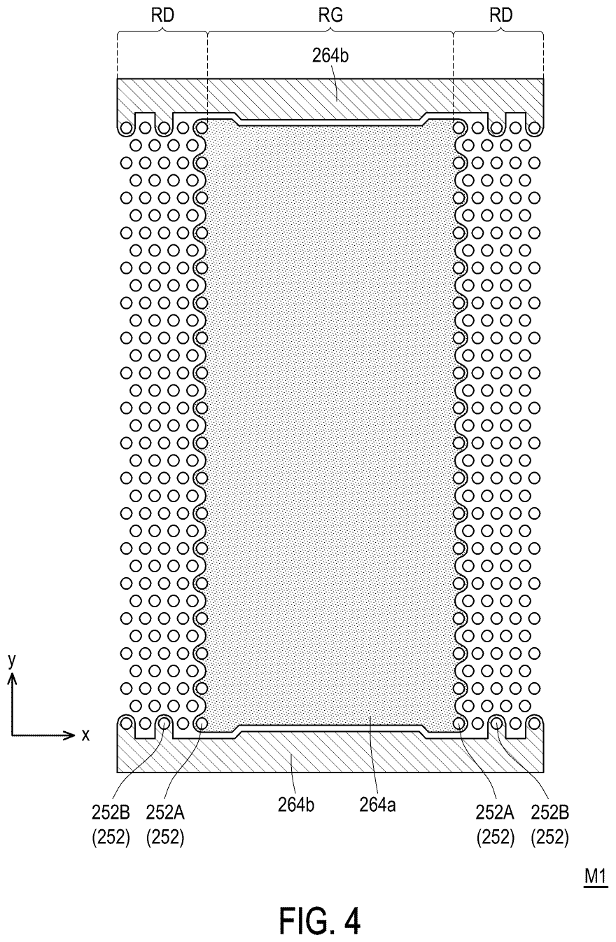

FIG. 4 schematically illustrates a top view of a portion of the metal layer M1 in the redistribution circuitry structure of FIG. 2 in accordance with some embodiments of the disclosure. For descriptive purpose, FIG. 4 shows the die gap region RG and portions of the die regions RD where the semiconductor dies 210A and 210B depicted in FIG. 2 are located and FIG. 4 shows the pattern design of the metal layer M1 in a plane of the X direction and Y direction. In addition, FIG. 4 also shows the bonding structures 252 for connecting the semiconductor dies 210A and 210B to the interposer 220 depicted in FIG. 2. The bonding structures 252 includes first bonding structures 252A for transmitting the electric power and the boding structures 252B for connecting to the ground while other bonding structures 252 are configured for transmitting electric signals for the semiconductor dies 210A and 210B. The first bonding structures 252A and the second bonding structures 252B are arranged along the periphery of the semiconductor die 210A or 210B and are configured to be electrically connected to the passive component 230 depicted in FIG. 2, wherein the first bonding structures 252A are arranged adjacent to the die gap region RG. The metal layer M1 of the redistribution circuitry structure RDL may include a first top pattern 264a and second top patterns 264b. The first top pattern 264a is configure to deliver the electric power and extends from the die gap region RG toward the die region RD to connect with the first bonding structures 252A arrange along the boundary between the die gap region RG and the die region RD. The second top patterns 264b are linear patterns extending in the X direction and located at opposite sides of the first top pattern 264a in the Y direction. The second top patterns 264b extend from the die gap region RG toward the die regions RD to connect with the second bonding structures 252B located at the periphery of the die regions RD. The first top pattern 264a occupies most area of the die gap region RG as a lump pattern, but the disclosure is not limited thereto.

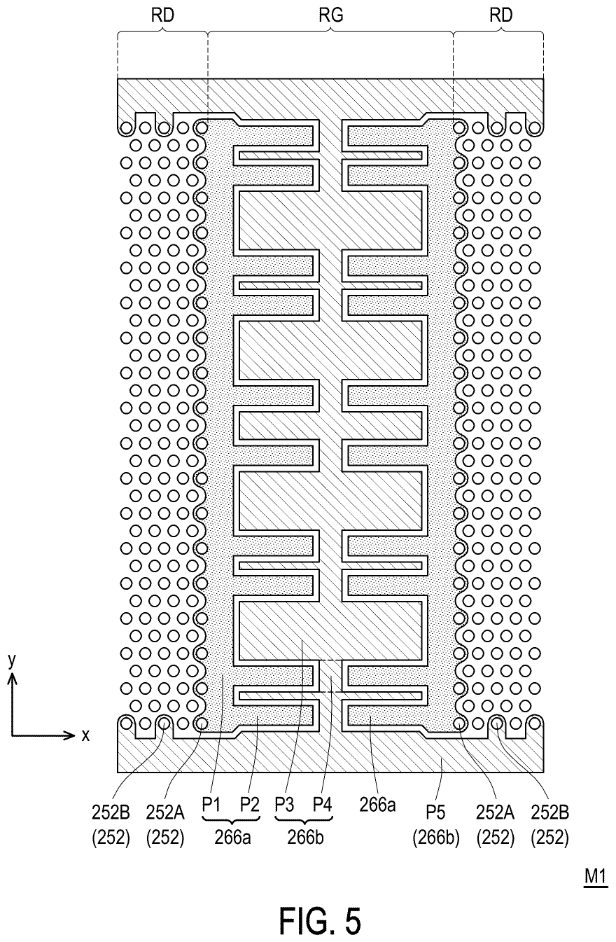

FIG. 5 schematically illustrates a top view of a portion of the metal layer M1 in the redistribution circuitry structure of FIG. 2 in accordance with some embodiments of the disclosure. For descriptive purpose, FIG. 5 also shows the bonding structures 252 for connecting the semiconductor dies 210A and 210B to the interposer 220 depicted in FIG. 2. The arrangement of the bonding structures 252 shown in FIG. 5 is the same as that depicted in FIG. 4. Specifically, the bonding structures 252 includes the first bonding patterns 252A and the second bonding patterns 252B arranged along the periphery of each die region RD, wherein the first bonding structures 252A are located between the die gap region RG and the die region RD. The metal layer M1 in the die gap region RG includes first top patterns 266a and a second top patterns 266b arranged in the die gap region RG and extends toward the die regions RD at opposite sides of the die gap region RG in the X direction.

The first top patterns 266a are located at opposite sides of the second top pattern 266b in the X direction. Each of the first top patterns 266a extends to overlap one of the die regions RD. Each of the first top patterns 266a includes an elongated portion P1 extends along the boundary between the die gap region RG and one of the die region RD in the Y direction and finger portions P2 connected to the elongated portion P1. The elongated portion P1 of each first top pattern 266a partially overlaps one of the die regions RD and connected/overlapped with the first bonding structures 252A. The finger portions P2 of each first top pattern 266a extends from the elongated portion P1 toward the other first top pattern 266a in the X direction. The finger portions P2 of the two first top pattern 266a may point to each other, but the disclosure is not limited thereto. The second top pattern 266b includes widen portions P3 extending between the elongated portions P1 of the two first top patterns 266a and neck portions P4 located between finger portions P2 of the two first top patterns 266a. A width of each widen portions P3 in the Y direction is greater than a width of the neck portions P4 in the Y direction. In addition, the second top pattern 266b may also include periphery portions P5 extending along the peripheries of the die regions RD in the X direction to connect with the second bonding structures 252b.

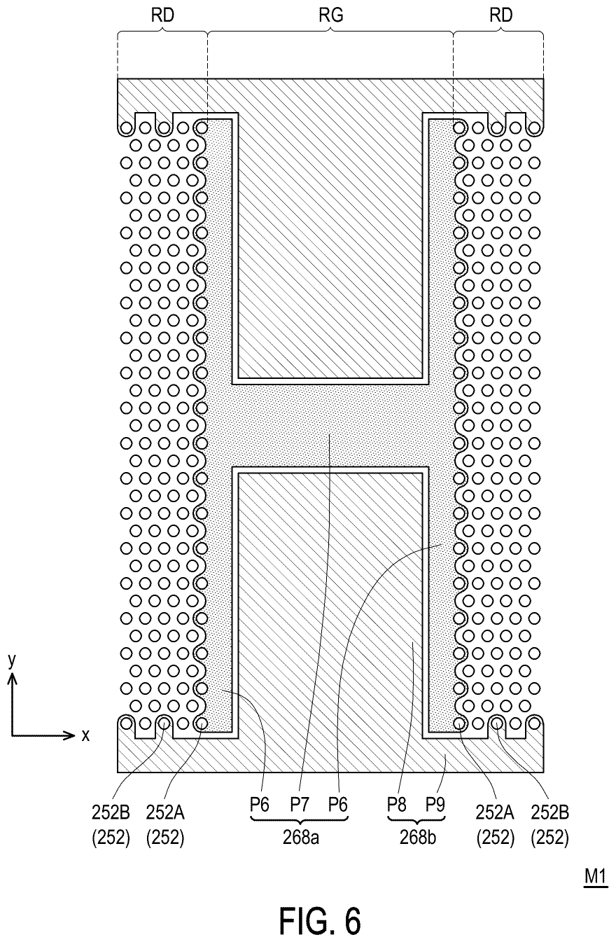

FIG. 6 schematically illustrates a top view of a portion of the metal layer M1 in the redistribution circuitry structure of FIG. 2 in accordance with some embodiments of the disclosure. In addition, for descriptive purpose, FIG. 6 also shows the bonding structures 252 for connecting the semiconductor dies 210A and 210B to the interposer 220 depicted in FIG. 2. The arrangement of the bonding structures 252 shown in FIG. 6 is the same as that depicted in FIG. 4. Specifically, the bonding structures 252 includes the first bonding structures 252A and the second bonding structures 252B arranged along the periphery of each die region RD, wherein the first bonding structures 252A are located between the die gap region RG and the die region RD. In FIG. 6, the metal layer M1 in the die gap region RG includes a first top pattern 268a and second top patterns 268b. The first top pattern 268a includes elongated portions P6 and a connecting portion P7 continuously extending between the elongate portions P6 in the X direction. Each of the elongated portions P6 extends along the boundary between the die gap region RG and a corresponding one of the die regions RD and partially overlaps the corresponding die region RD to connect with the first bonding structure 252A. The second top patterns 268b are located at opposite sides of the connecting portion P7 of the first top pattern 268a in the Y direction. Each of the second top patterns 268b includes a lump portion P8 in the die gap region RG and a periphery portion P9 extending along the periphery of the die regions RD in the X direction to connect with the second bonding structures 252B.

FIG. 3 schematically illustrate an embodiment of the top view design for implementing the bottom pattern 222B of the gap conductive feature 222 in the metal layer Mx of the interposer 220 depicted in FIG. 2, and FIG. 4 to FIG. 6 schematically illustrate various embodiments of the top view design for implementing the top pattern 222A of the gap conductive feature 222 in the metal layer M1 of the interposer 220 depicted in FIG. 2. In some embodiments, the intermediate patterns 222C arranged in the other metal layers M2 . . . Mx−1 may be designed based on the pattern designs of the top pattern 222A and the bottom pattern 222B to form a continuous electric transmission path for providing the first gap electric transmission pathway 122A and the second gap electric transmission pathway 122B depicted in FIG. 1. In some embodiments, each of the gap electric transmission pathways 122 depicted in FIG. 1 may be implemented by the cross-sectional structure of the gap conductive feature 222 shown in FIG. 2. In some embodiments, the top pattern 222A for the first gap electric transmission pathway 122A may be implemented by any of the first top patterns 264a, 266a and 268a in FIG. 4 to FIG. 6 and the top pattern 222A for the second gap electric transmission pathway 122B may be implemented by any of the second top patterns 264b, 266b and 268b in FIG. 4 to FIG. 6. In some embodiments, the bottom pattern 222B for the first gap electric transmission pathway 122A may be implemented by the first bottom patterns 262a in FIG. 3 and the bottom pattern 222B for the second gap electric transmission pathway 122B may be implemented by the second bottom patterns 262b in FIG. 3.

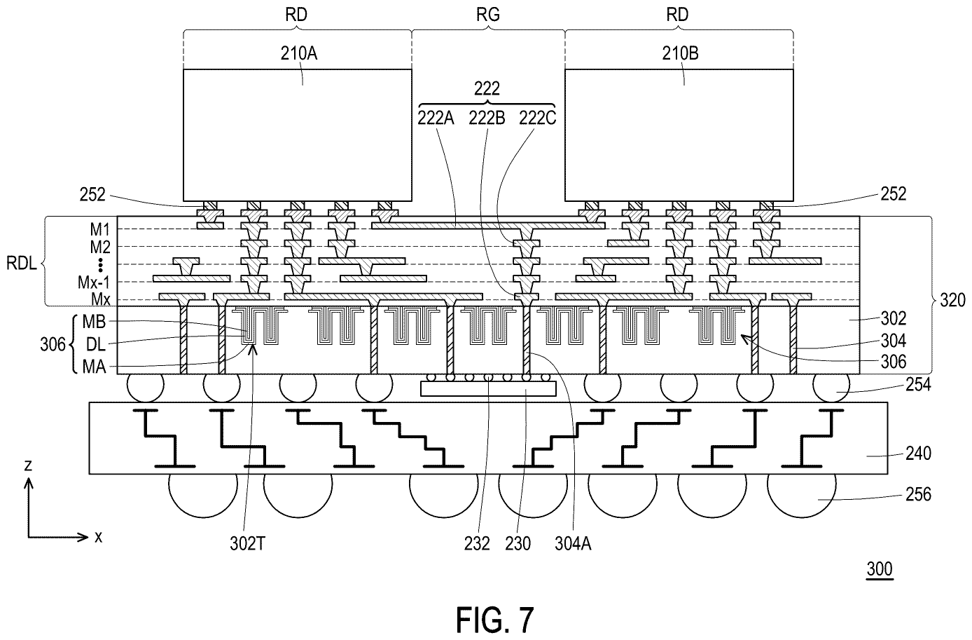

FIG. 7 schematically illustrates a sectional view of an electronic device in accordance with some embodiments of the disclosure. An electronic device 300 is similar to the electronic device 200, but different from the electronic device 200 in the design of the interposer 320. Accordingly, some components denoted by the same reference numbers in FIG. 2 and FIG. 7 may be the same or equivalent components and the description for these components in different embodiments may refer to each other. Specifically, the electronic device 300 includes semiconductor dies 210A and 210B, an interposer 320, a passive component 230 and a package substrate 240, wherein the interposer 320 includes a redistribution circuitry structure RDL, a substrate 302, through substrate vias 304 and embedded passive components 306. The embedded passive components 306 may be decoupling capacitors, such as Embedded deep trench capacitors (eDTCs). Herein, the disposition relationships, the structures, the materials, the functions or the like of the semiconductor dies 210A and 210B, the redistribution circuitry structure RDL, the passive component 230 and the package substrate 240 may refer to the description depicting those components of FIG. 2 and not reiterate.

In the embodiment, the redistribution circuitry structure RDL is disposed on the substrate 302 at a side adjacent to the semiconductor dies 210A and 210B. In other words, the redistribution circuitry structure RDL is located between the substrate 302 and the semiconductor dies 210A and 210B. The through substrate vias 304 extend through the substrate 302 in the thickness direction (the Z direction) and electrically connected to the redistribution circuitry structure RDL. The embedded passive components 306 are disposed between the substrate 302 and the redistribution circuitry structure RDL. The embedded passive components 306 may be partially embedded in the substrate 302, and/or partially embedded in an interconnect structure (not shown) disposed between the substrate 302 and the redistribution circuitry structure RDL. The interposer 320 is bonded to the package substrate 240 through the bonding structures 254 located between the substrate 302 and the package substrate 240 and the through substrate vias 304 are electrically connected to the bonding structures 254. The passive component 230 is bonded to the substrate 302 of the interposer 320 through the bonding structures 232 and located between the substrate 302 and the package substrate 240. The semiconductor dies 210A and 210B are bonded to the redistribution circuitry structure RDL of the interposer 320 through the bonding structures 252. The through substrate vias 304 electrically connect the redistribution circuitry structure RDL to the passive component 230 as well as the package substrate 240.

In the embodiment, at least one of the through substrate vias 304 is located in the die gap region RG, such as the through substrate via 304A. The through substrate via 304A in the die gap region RG may be electrically connected between the gap conductive feature 222 formed in the redistribution circuitry structure RDL and the passivation component 230. In addition, the through substrate via 304A and the gap conductive feature 222 may form the gap electric transmission pathway 122 depicted in FIG. 1. The through substrate via 304A and the gap conductive feature 222 located in the die gap region RG may form a short electric transmission pathway between the passive component 230 and the semiconductor dies 210A and 210B, which helps to reduce the transmission resistance and the inductance and thus ensures the decoupling effect provided by the passive component 230. FIG. 7 only shows one gap conductive feature 222 for descriptive purpose, but the interposer 320 may include multiple gap conductive features 222 for transmitting various signals. For example, at least one of the gap conductive features 222 is configured to deliver the electric power and at least another of the gap conductive features 222 is configured to electrically connect to the ground.

In the embodiment, the embedded passive component 306 is formed in the trenches 302T of the substrate 302 and include a first electrode layer MA, a second electrode layer MB and a dielectric layer DL isolating the first electrode layer MA from the second electrode layer MB. The first electrode layer MA, the dielectric layer DL and the second electrode layer MB are sequentially disposed on the substrate 302 and conformally extend along the shape of the trenches 302T. The embedded passive component 306 and the passive component 230 may provide a similar function such as the decoupling function. The interposer 320 may include multiple embedded passive components 306 and multiple conductive features 222 while one of the embedded passive components 306 may be located in the die gap region RG and electrically connected to the semiconductor dies 210A and 210B through one of the gap conductive features 222, such that the electric transmission path between the embedded passive component 306 and the semiconductor dies 210A and 210B is short.

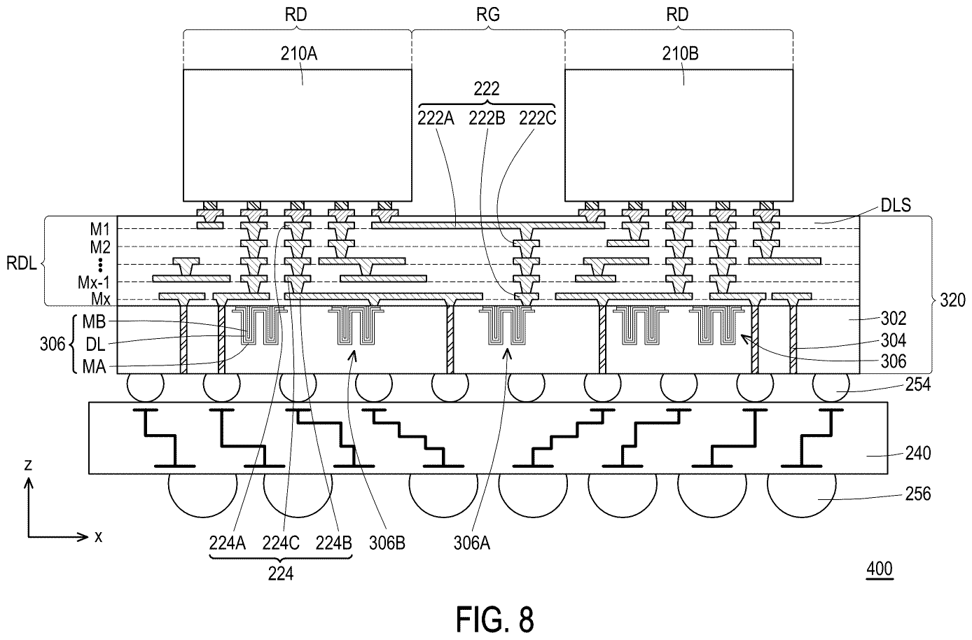

FIG. 8 schematically illustrates a sectional view of an electronic device in accordance with some embodiments of the disclosure. An electronic device 400 shown in FIG. 8 is similar to the electronic device 300 shown in FIG. 7. Some components denoted by the same reference numbers in FIG. 7 and FIG. 8 may be the same or equivalent components and the description for these components in different embodiments may refer to each other. The electronic device 400 includes semiconductor dies 210A and 210B, an interposer 320, and a package substrate 240. In FIG. 8, the passive component 230 in FIG. 7 may be omitted. Similar to the above embodiment, the semiconductor dies 210A and 210B are laterally spaced from each other by a die gap region RG and bonded onto the interposer 320. The interposer 320 is bonded onto the package substrate 240.

In the embodiment, the interposer 320 includes a redistribution circuitry structure RDL, a substrate 302, through substrate vias 304 and a plurality of embedded passive components 306. The redistribution circuitry structure RDL disposed on the substrate 302 and includes a dielectric structure DLS and metal layers M1 . . . Mx embedded in the dielectric structure DLS to provides a gap electric transmission pathway in the die gap region RG. For example, the gap electric transmission pathway in the die gap region RG may perform the function similar to the gap electric transmission pathway 122 depicted in FIG. 1. In some embodiments, the metal layers M1 . . . Mx construct a gap conductive feature 222 in the die gap region RG to form the gap electric transmission pathway. The embedded passive components 306 disposed between the substrate 302 and the redistribution circuitry structure RDL. At least one of the embedded passive components 302, such as the embedded passive component 306A is electrically connected to the semiconductor dies 210A and 210B through the gap electric transmission pathway formed by the gap conductive feature 222.

In the embodiment, the gap conductive feature 222 includes a top pattern 222A in one of the metal layers, i.e. the metal layer M1, most adjacent to the semiconductor dies 210A and 210B, and the top pattern 222A laterally extends from the die gap region RG toward the semiconductor dies 210A and 210B and partially overlaps the semiconductor dies 210A and 210B. The gap conductive feature 222 also includes a bottom pattern 222B in another one of the metal layers, i.e. the metal layer Mx most adjacent to the substrate 302 and intermediate patterns 222C in intermediate ones of the metal layers, i.e. the metal layers M2 . . . Mx−1 between the metal layer M1 and the metal layer Mx. The intermediate patterns 222C are arranged along a thickness direction Z between the top pattern 222A and the bottom pattern 222B. In the embodiment, the bottom pattern 222B may be connected to the embedded passive component 306A through a corresponding through via.

In addition, the metal layers M1 . . . Mx may further construct an underneath conductive feature 224 in a die region RD where one of the semiconductor dies 210A and 210B is. The underneath conductive feature 224 is electrically connected between at least another one of the embedded passive components, such as the embedded passive component 306B, and the one of the semiconductor dies, such as the semiconductor die 210A. The underneath conductive feature 224 in the die region RD includes a top pattern 224A, a bottom pattern 224B and intermediate patterns 224C, which are similar to those depicted in FIG. 2. In the embodiment, the bottom pattern 224B is connected to the embedded passive component 306B through a corresponding through via and the bottom pattern 224B may laterally extend from the die region RD toward the die gap region RG to partially overlaps the embedded passive component 306A.

In view of the above, the electronic device includes semiconductor dies boned on a first surface of an interposer in a side-by-side manner and a passive component bonded on a second surface of the interposer at a die gap region between the semiconductor dies. The interposer in the embodiments provides an electric transmission pathway between the passive component and the semiconductor dies in the die gap region. Accordingly, the electric transmission path between the passive component and the semiconductor dies is short, which helps to reduce the transmission resistance and inductance and ensures the decoupling effect of the passive component.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An electronic device, comprising:
semiconductor dies laterally spaced from each other by a die gap region;
an interposer, the semiconductor dies being bonded onto a first surface of the interposer, wherein the interposer provides a gap electric transmission pathway in the die gap region, the gap electric transmission pathway extends from the first surface of the interposer to a second surface of the interposer, and the second surface is opposite to the first surface; and
a passive component bonded onto the second surface of the interposer, and located in the die gap region, wherein the passive component is electrically connected to the semiconductor dies through the gap electric transmission pathway.

2. The electronic device of claim 1, wherein the interposer comprises a redistribution circuitry structure, and the redistribution circuitry structure comprises a dielectric structure and metal layers are embedded in the dielectric structure.

3. The electronic device of claim 2, wherein the metal layers construct a gap conductive feature in the die gap region to form the gap electric transmission pathway.

4. The electronic device of claim 3, wherein the gap conductive feature includes a top pattern in one of the metal layers most adjacent to the first surface, and the top pattern laterally extends from the die gap region toward the semiconductor dies and partially overlaps the semiconductor dies.

5. The electronic device of claim 4, wherein the top pattern of the gap conductive feature is a lump pattern in the die gap region.

6. The electronic device of claim 4, wherein the gap conductive feature comprises a bottom pattern in another one of the metal layers most adjacent to the second surface, intermediate patterns in intermediate ones of the metal layers between the one and the another one of the metal layers, and the intermediate patterns are arranged along a thickness direction between the top pattern and the bottom pattern.

7. The electronic device of claim 6, wherein the bottom pattern and the intermediate patterns are located in the die gap region.

8. The electronic device of claim 2, wherein the metal layers construct an underneath conductive feature in a die region where one of the semiconductor dies is and the underneath conductive feature is electrically connected between the passive component and the one of the semiconductor dies.

9. The electronic device of claim 8, wherein the underneath conductive feature in the die region includes a bottom pattern in one of the metal layers most adjacent to the second surface, and the bottom pattern laterally extends from the die region toward the die gap region and partially overlaps the passive component.

10. The electronic device of claim 2, wherein the interposer further comprises a substrate and through substrate vias, the redistribution circuitry structure is disposed on the substrate, the through substrate vias extend through the substrate in a thickness direction and electrically connected to the redistribution circuitry structure.

11. The electronic device of claim 10, wherein one of the through substrate via located in the die gap region forms the gap electric transmission pathway.

12. The electronic device of claim 10, wherein the interposer further comprises an embedded passive component disposed between the substrate and the redistribution circuitry structure.

13. The electronic device of claim 12, wherein the interposer further provides another gap electric transmission pathway in the die gap region, and the embedded passive component is electrically connected to the semiconductor dies through the another gap electric transmission pathway.

14. The electronic device of claim 1, further comprising a package substrate, wherein the interposer is bonded to the package substrate and the passive component is located between the interposer and the package substrate.

15. The electronic device of claim 1, wherein the interposer further provides a lateral signal transmission pathway electrically connected between the semiconductor dies.

16. The electronic device of claim 1, wherein the gap electric transmission pathway is configured to transmit an electric power.

17. The electronic device of claim 1, wherein the gap electric transmission pathway is configured to be electrically grounded.

18. The electronic device of claim 1, further comprising bonding structures connecting each of the semiconductor dies to the interposer.

19. The electronic device of claim 18, wherein the bonding structures comprises first bonding structures and second bonding structures arranged along a periphery of the each of the semiconductor dies, and electrically connected to the passive component.

20. The electronic device of claim 18, wherein the first bonding structures transmit an electric power and the second bonding structures are electrically grounded.

21. An electronic device, comprising:
semiconductor dies laterally spaced from each other by a die gap region; and
an interposer, the semiconductor dies being bonded onto the interposer, wherein the interposer comprises:
a substrate;
a redistribution circuitry structure disposed on the substrate and comprises a dielectric structure and metal layers embedded in the dielectric structure to provide a gap electric transmission pathway in the die gap region; and
a plurality of embedded passive components disposed between the substrate and the redistribution circuitry structure, wherein at least one of the embedded passive components is electrically connected to the semiconductor dies through the gap electric transmission pathway.

22. The electronic device of claim 21, wherein the metal layers construct a gap conductive feature in the die gap region to form the gap electric transmission pathway.

23. The electronic device of claim 22, wherein the gap conductive feature comprises a top pattern in one of the metal layers most adjacent to the semiconductor dies, and the top pattern laterally extends from the die gap region toward the semiconductor dies and partially overlaps the semiconductor dies.

24. The electronic device of claim 23, wherein the gap conductive feature comprises a bottom pattern in another one of the metal layers most adjacent to the substrate and intermediate patterns in intermediate ones of the metal layers between the one and the another one of the metal layers, and wherein the intermediate patterns are arranged along a thickness direction between the top pattern and the bottom pattern.

25. The electronic device of claim 21, wherein the metal layers construct an underneath conductive feature in a die region where one of the semiconductor dies is and the underneath conductive feature is electrically connected between at least another one of the embedded passive components and the one of the semiconductor dies.

26. The electronic device of claim 25, wherein the underneath conductive feature in the die region includes a bottom pattern in one of the metal layers most adjacent to the substrate, and the bottom pattern laterally extends from the die region toward the die gap region and partially overlaps the at least one of the embedded passive components.
